(19) United States
(12) Patent Application Publication
(10) Pub. No.: US 2006/0145188 A1
(43) Pub. Date: Jul. 6, 2006

(54) Semiconductor wafer having a silicon-germanium layer, and method for its production

(75) Inventors: Dirk Dantz, Koenigslutter an Elm (DE); Andreas Huber, Garching (DE); Reinhold Wahlich, Tittmoning (DE)

Correspondence Address: BROOKS KUSHMAN P.C., 1000 TOWN CENTER, TWENTY-SECOND FLOOR, SOUTHFIELD, MI, 48075, US

(73) Assignee: Siltronic AG, Munich (DE)

(21) Appl. No.: 11/324,874

(22) Filed: Jan. 3, 2006

(30) Foreign Application Priority Data
Jan. 5, 2005 (DE) 10 2005 000 826.7

(51) Int. Cl. H01L 31/109

(52) U.S. Cl. 257/191; 438/936

(57) ABSTRACT

A semiconductor wafer has a monocrystalline silicon layer and a graded silicon-germanium layer adjacent thereto, of thickness d and composition Si₁₋ₓGeₓ, where x represents the proportion of germanium and 0<x≦1, and where x assumes greater values with increasing distance a from the monocrystalline silicon layer, wherein the relationship between the proportion x(d) of germanium at the surface of the graded silicon-germanium layer and the proportion x(d/2) of germanium at the center distance between the monocrystalline silicon layer and the surface of the graded silicon-germanium layer is x(d/2)>0.5·x(d). The wafer may be further processed, in which process a layer of the semiconductor wafer is transferred to a substrate wafer.

### BACKGROUND OF THE INVENTION

1. Field of the Invention

The invention relates to a semiconductor wafer comprising a monocrystalline silicon layer and a silicon-germanium layer adjacent to it, in which the proportion of germanium increases towards the surface, and to a method for production of the semiconductor wafer. The subject matter of the invention also includes the further processing of the semiconductor wafer, in which a layer of the semiconductor wafer is transferred to a substrate wafer, and to semiconductor wafers produced in this way.

2. Background Art

In a known method for the production of relaxed silicon-germanium layers, lattice matching between silicon and silicon-germanium is achieved first of all by deposition of silicon-germanium layers with an increasing germanium content; referred to in the following text as a “graded silicon-germanium layer”. The profile of the germanium concentration is described in the prior art either as “linear” or “stepped”. The silicon-germanium layer which overlies this layer and has a constant proportion of germanium is used for reducing the mechanical stress on the silicon-germanium layer. The surface roughnesses which occur in this method can optionally be reduced by subsequent and/or intermediate polishing steps.

According to the prior art, see, for example, U.S. Pat. No. 6,593,625 or U.S. Pat. No. 6,107,653, the profile of the proportion of germanium in the graded intermediate layer is described as “linear” or “stepped”. These graded silicon-germanium layers have dislocation densities of 10⁶ to 10⁷ cm⁻² at their surface. If a strained silicon layer is deposited on the silicon-germanium layer, then this strained silicon layer has a similar dislocation density. If the silicon-germanium layer or the strained silicon layer is transferred to a substrate wafer, in order to produce an SGOI (silicon-germanium on insulator) substrate or an sSOI (strained silicon on insulator) substrate, then the transferred layer likewise has a dislocation density in the stated range. This dislocation density is sufficiently high that it has a disadvantageous effect on the electronic characteristics of the electronic components produced on these substrates. Even after planarization of the graded silicon-germanium layer, for example by chemical/mechanical polishing (CMP) as disclosed in U.S. Pat. No. 6,107,653, the dislocation density in the upper area of the silicon-germanium layer is in the region of 10⁵ cm⁻².

### SUMMARY OF THE INVENTION

One object of the invention was thus to reduce the dislocation densities in graded silicon-germanium layers. This and other objects are achieved by a semiconductor wafer comprising a monocrystalline silicon layer and a graded silicon-germanium layer of thickness d adjacent thereto, the graded silicon-germanium layer having a composition Si₁₋ₓGeₓ, where x represents the proportion of germanium and 0<x≦1, and where x assumes greater values as a distance a from the monocrystalline silicon layer increases, wherein the relationship between the proportion x(d) of germanium at the surface of the graded silicon-germanium layer and the proportion x(d/2) of germanium in the center of the distance between the monocrystalline silicon layer and the surface of the graded silicon-germanium layer is as follows: x(d/2)>0.5·x(d).

### BRIEF DESCRIPTION OF THE DRAWINGS

FIGS. 1 to 4 show various concentration profiles in the graded intermediate layer. The proportion x of germanium is in each case plotted against the distance a from the monocrystalline silicon layer.

FIG. 1 shows one example of a profile according to the invention of the proportion x of germanium with a decreasing gradient as the distance a from the monocrystalline silicon layer increases, which can be described by a function which can be continuously differentiated.

FIG. 2 shows an example of a profile according to the invention of the proportion x of germanium with a decreasing gradient as the distance from the monocrystalline silicon layer increases, which can be described by a step function which cannot be differentiated continuously, in which the individual layers have a constant thickness and the height of the steps decreases from one layer to the next.

FIG. 3 shows an example of continuous variation of the proportion x of germanium with a decreasing gradient as the concentration increases, in which the increasing concentration profile is interrupted by two thin layers 1 with a lower germanium concentration.

FIG. 4 shows an example similar to the stepped profile in FIG. 2, in which additional buffer layers 2 are integrated in the graded silicon-germanium layer.

### DETAILED DESCRIPTION OF THE PREFERRED EMBODIMENTS

According to the invention, the rise in the proportion x of germanium as the distance a from the monocrystalline silicon layer increases is thus not linear or constant in the form of a step (that is to say with the same sudden concentration changes after constant layer thicknesses, for example as disclosed in U.S. Pat. No. 6,107,653), but has a decreasing gradient. The process preferably starts with the deposition of pure silicon on the surface of the monocrystalline silicon layer. The silicon layer may either be a thin layer on a suitable substrate material or, which is preferable, may be a monocrystalline silicon wafer. At the start of the deposition of the graded silicon-germanium layer, the proportion of germanium rises relatively quickly according to the invention while, in contrast, the gradient decreases as the germanium content rises, that is to say with increasing distance from the monocrystalline silicon layer or towards the end of the deposition process. This situation is expressed by the relationship x(d/2)>0.5·x(d). At the half-thickness point in the graded silicon-germanium layer, the proportion of germanium is thus already higher than would be the case with a linear gradient, since the proportion of germanium initially rises comparatively steeply, and then in a flatter form in the further profile. The profile of the proportion of germanium preferably may even differ from the linear gradient to such an extent that the inequality x(d/2)>0.6·x(d) is satisfied.

Higher stresses and thus also higher dislocation densities than those for conventional linear grading are thus produced in the first, that is to say lowest, layers of the graded silicon-germanium layer and can then be decreased in the further profile in the layers with comparatively minor changes in the composition. The later, flatter grading, results in only a small number of additional dislocations close to the surface and, in the end, this leads to a greatly reduced dislocation density. The matching of the concentration gradients to the mechanical loads resulting from the layer structure offers the capability to influence the stresses that occur as a result of lattice mismatching to such an extent that the formation of dislocations is minimized overall and is restricted to areas in which they have no negative effects, or far less negative effects, for subsequent processes and subsequent applications. According to the invention, a reduced dislocation density is thus achieved at the surface than that achieved by the prior art with the same overall thickness of the graded silicon-germanium layer, that is to say the quality of the silicon-germanium surface is improved. On the other hand, the overall thickness of the graded silicon-germanium layer can be reduced in comparison to the prior art for a predetermined dislocation density, thus making production more economic.

The overall thickness d of the graded silicon-germanium layer is preferably 0.5 to 10 μm, and in particular, 1 to 5 μm.

An additional silicon-germanium layer which may possibly be deposited on the graded silicon-germanium layer and has a constant proportion of germanium is not considered to be part of the graded silicon-germanium layer, according to the invention. Thus, for the graded silicon-germanium layer according to the invention, the relationship x(d/2)<x(d) is in each case satisfied in addition to the inequalities stated above, preferably even x(d/2)<0.9·x(d) and more preferably x(d/2)<0.85·x(d).

Thus, overall, a relationship of 0.9·x(d)>x(d/2)>0.5·x(d) is very preferable, and a relationship of 0.85·x(d)>x(d/2)>0.6·x(d) is especially preferred.

According to the invention, a dislocation density of less than 1·10⁴ cm⁻² is achieved at the surface of the deposited graded silicon-germanium layer. Very low dislocation densities down to 100 cm⁻² or even 10 cm⁻² can thus be achieved using the method according to the invention.

The object is also achieved by a method for production of a semiconductor wafer according to the invention, in which silicon-germanium with a composition Si₁₋ₓGeₓ, where x represents the proportion of germanium and 0<x≦1, is deposited epitaxially on a semiconductor wafer comprising a monocrystalline silicon layer, where x assumes greater values as the thickness of the deposited layer increases, wherein the increase in x slows down as the thickness of the deposited layer increases.

Methods for deposition of graded silicon-germanium layers are known from the prior art. While observing the condition that the increase in the proportion x of germanium slows down with increasing thickness of the deposited silicon-germanium layer, the deposition of the graded silicon-germanium layer is carried out, by way of example, as is described in U.S. Pat. No. 6,107,653.

The invention will be described in more detail in the following text together with preferred embodiments and with reference to the figures.

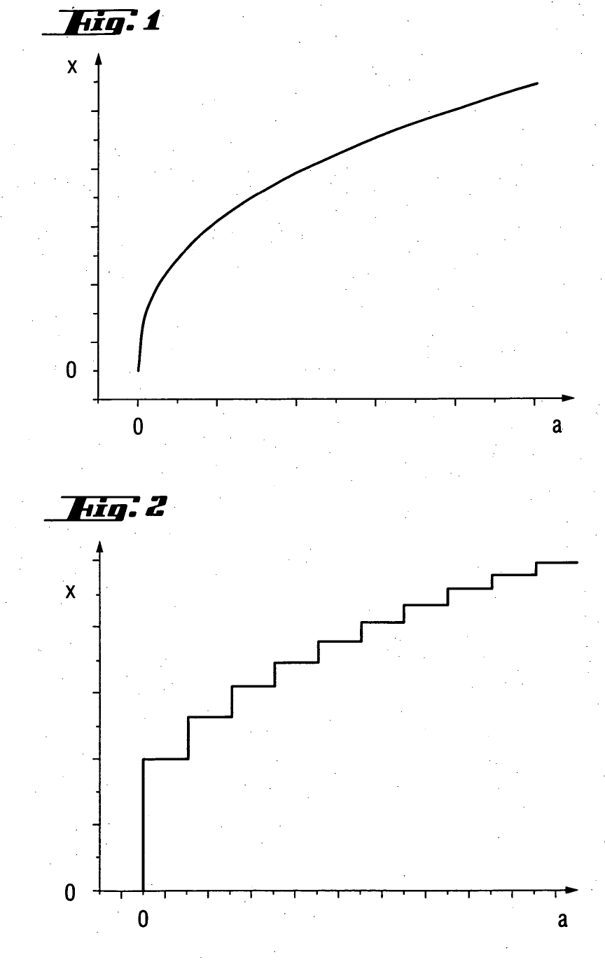

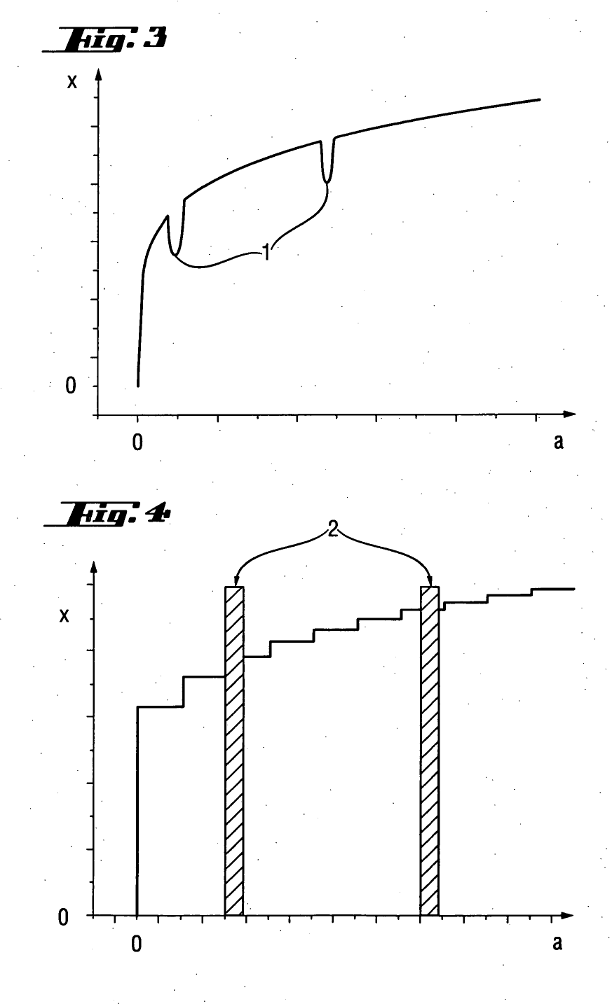

The concentration profiles according to the invention can be achieved in various ways. Functions which describe the concentration profile may be in a form in which they can be differentiated continuously (FIGS. 1, 3). This means that the deposition takes place with a continuous change in the germanium concentration. On the other hand, the concentration profile according to the invention can also be represented by a function which cannot be differentiated continuously, that is to say, for example, a step function (FIGS. 2, 4). In the case of this layer-type structure, the decreasing gradient of the germanium concentration is achieved either by a constant change in the germanium concentration in the individual layers as the thickness of the individual layers increases (not illustrated), or by a decreasing change in the germanium concentration with the thickness of the individual layers being constant (FIGS. 2, 4). A combination of these two versions is also possible.

In another preferred embodiment of the invention, the non-linear change in the composition according to the invention is combined with intermediate layers in which the germanium concentration is changed locally in one or more thin layers in a contrary manner to the general concentration profile. FIG. 3 shows an example in which the proportion x of germanium in two thin layers 1 is reduced in a locally limited form to considerably lower values. The stress relief which this creates, allows dislocations that have already taken place to be dissipated again, while at the same time preventing dislocations from propagating into the following layers. However, it is also possible to increase the germanium concentration in a locally limited form to considerably higher values, thus producing a local concentration maximum.

In a further embodiment of the invention, which is illustrated schematically in FIG. 4, one or more buffer layers 2, which are preferably rich in defects, have a different composition and are integrated in the graded silicon-germanium layer, and interrupt the concentration profile. These buffer layers are likewise able to dissipate stresses resulting from lattice mismatching and to prevent the propagation of dislocations. By way of example, these layers may be composed of Si_{1-x-y}GeₓC_{y} where 0<x<1.0<y<1 and x+y<1.

In a further preferred embodiment of the invention, a silicon-germanium layer with a constant proportion of germanium is additionally deposited on the graded layer, in which the proportion x of germanium rises to a predetermined limit value as the distance a from the monocrystalline silicon layer (a=0) rises to a predetermined limit value which is reached at the surface of the graded silicon-germanium layer (a=d), with the germanium content in this cover layer preferably corresponding to the germanium content in the uppermost part of the graded layer. The cover layer may also be composed of pure germanium, that is to say x=1. According to the invention, the cover layer likewise has a dislocation density at the surface of less than 1·10⁴ cm⁻². Semiconductor wafers such as these are preferably used as a donor wafer for production of SGOI wafers. This embodiment can be combined as required with the various embodiments of the graded intermediate layer (concentration profile which can be differentiated continuously or a step function, with or without layers with a different germanium concentration or additional buffer layers with a different composition).

One embodiment of the invention provides for the deposition of a strained silicon layer on the silicon-germanium layer. The strained silicon layer thickness is preferably 3 to 20 nm. The strained silicon layer may be deposited on any silicon-germanium layer according to the invention. The exact characteristics of the graded silicon-germanium layer and the possibility of a silicon-germanium layer with a constant composition being present are not significant in this context. The surface of the silicon-germanium layer on which the strained silicon layer is intended to be deposited is preferably relaxed, and preferably has a composition of 0.1<x<0.9, most preferably of 0.1<x<0.5.

All of the semiconductor wafers according to the invention can also be used as donor wafers in a layer transfer process. For this purpose, the semiconductor wafer is connected to a substrate wafer in a known manner on the prepared surface to which the layer to be transferred has been applied, and the thickness of the donor wafer is then reduced in such a way that only the layer to be transferred now remains on the substrate wafer. Methods for transferring a thin semiconductor layer to a substrate wafer are described, by way of example, in EP533551A1, WO98/52216A1 or WO03/003430A2. By way of example, an electrically insulating wafer (composed, for example, of quartz, glass or sapphire) can be used as substrate wafer, or the surface of the donor wafer and/or of the substrate wafer is provided with an insulating layer, for example an oxide layer, before connection. A silicon wafer, in particular a monocrystalline silicon wafer, is preferably used as the substrate wafer, the surface of which is oxidized such that a silicon oxide layer forms the electrically insulating layer. Methods for production of this insulating layer and for connection (bonding) of wafers are known to those skilled in the art. The use of donor wafers according to the invention leads to dislocation densities in the transferred layers which are lower than in the case of the prior art.

If the intention is to transfer a silicon-germanium layer to a substrate wafer, then a semiconductor wafer according to the invention is used as a donor wafer, whose surface has a proportion x of germanium which satisfies the condition 0<x<1. A semiconductor wafer according to the invention with an additional silicon-germanium layer (cover layer) with a constant proportion of germanium is preferable for this application. The proportion of germanium is preferably in the range 0.1<x<0.9, and more preferably in the range 0.1<x<0.5. If, in particular, the intention is to produce an SGOI (silicon-germanium on insulator) wafer, then an electrically insulating wafer is used as the substrate wafer, or the surface of the donor wafer and/or of the substrate wafer is provided with an insulating layer, for example an oxide layer, before connection. After the transfer, the silicon-germanium layer has a dislocation density of less than 1·10⁴ cm⁻².

If the intention is to transfer a germanium layer to a substrate wafer, then a substrate wafer according to the invention is used as a donor wafer which has a layer of pure germanium on its surface, that is to say its proportion of germanium is x=1. If the intention is, in particular, to produce a GOI (germanium on insulator) wafer, then an electrically insulating wafer is used as the substrate wafer, or the surface of the donor wafer and/or of the substrate wafer is provided with an insulating layer, for example an oxide layer, before connection. After the transfer, the germanium layer has a dislocation density of less than 5·10⁵ cm⁻².

If the intention is to transfer a strained silicon layer to a substrate wafer, then a semiconductor wafer according to the invention is used as a donor wafer, to whose surface a strained silicon layer has been applied, which was deposited on a silicon-germanium layer. This silicon-germanium layer has a proportion x of germanium which satisfies the condition 0<x<1. The surface of the silicon-germanium layer on which the strained silicon layer is intended to be deposited is preferably relaxed and preferably has a composition of 0.1<x<0.9, and more preferably of 0.1<x<0.5. If the intention is, in particular, to produce an sSOI (strained silicon on insulator) wafer, then an electrically insulating wafer is used as the substrate wafer, or the surface of the donor wafer and/or of the substrate wafer is provided with an insulating layer, for example an oxide layer, before connection. After the transfer, the strained silicon layer has a dislocation density of less than 1·10⁴ cm⁻².

### EXAMPLE

A cleaned, monocrystalline <001>-oriented silicon wafer was loaded into a CVD reactor with reduced pressure capability. The oxygen remaining on the surface of the silicon wafer and the remaining carbon were removed by purging with hydrogen at a pressure of 1.3·10⁻⁵ Pa and a temperature of 1050° C. First of all, a monocrystalline silicon layer with a thickness of 50 nm was deposited epitaxially at 900° C. and 530 Pa, using dichlorosilane (SiH₂Cl₂). Hydrogen was used as the carrier gas. The epitaxial deposition of the graded layer was started immediately after this. Germanium tetrahydride (GeH₄) was additionally passed into the process chamber for this purpose. The germanium tetrahydride flow was strong at the start of the deposition of the graded layer (the flow gradient is increased by 8 sccm every 30 seconds), and became ever weaker as the process continued (at the end of the deposition: the flow gradient is increased by 1 sccm every 30 seconds). The dichlorosilane flow was in each case reduced by the same amount. The proportion of germanium for a layer thickness of 1.5 μm (d/2) was 20%. The proportion of germanium in the deposited layer at the end of the deposition process was 30%. The overall thickness d of the silicon-germanium layer was 3 μm. The dislocation density at the surface of the layer was 9·10³ cm⁻².

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A semiconductor wafer, comprising a monocrystalline silicon layer and a graded silicon-germanium layer, which is adjacent to it, of thickness d with a composition Si₁₋ₓGeₓ, where x represents the proportion of germanium and 0<x≦1, and where x assumes greater values with increasing distance a from the monocrystalline silicon layer, wherein the relationship between the proportion x(d) of germanium at the surface of the graded silicon-germanium layer and the proportion x(d/2) of germanium in the center of the distance between the monocrystalline silicon layer and the surface of the graded silicon-germanium layer is: x(d/2)>0.5·x(d).

2. The semiconductor wafer of claim 1, wherein the relationship is x(d/2)>0.6·x(d).

3. The semiconductor wafer of claim 1, wherein the further relationship x(d/2)<0.9·x(d) is also satisfied.

4. The semiconductor wafer of claim 2, wherein the relationship x(d/2)<0.85·x(d) is also satisfied.

5. The semiconductor wafer of claim 1, wherein the semiconductor wafer has an additional silicon-germanium layer which is adjacent to the graded silicon-germanium layer, the additional layer having a substantially constant proportion of germanium.

6. The semiconductor wafer of claim 1, wherein the proportion x of germanium in the graded silicon-germanium layer rises in the form of a function which can be differentiated continuously with respect to the distance a from the monocrystalline silicon layer.

7. The semiconductor wafer of claim 1, wherein the proportion x of germanium in the graded silicon-germanium layer rises in the form of a step function with respect to the distance a from the monocrystalline silicon layer.

8. The semiconductor wafer of claim 1, wherein the proportion x of germanium in the graded silicon-germanium layer rises in the form of a monotonally rising function of the distance a from the monocrystalline silicon layer.

9. The semiconductor wafer of claim 1, wherein the graded silicon-germanium layer has at least one area at a distance from the monocrystalline silicon layer in which x decreases, starting from an initial value, as the distance from the monocrystalline silicon layer increases, has a local minimum and rises again to the initial value, or has an area at a distance in which x rises, starting from an initial value, as the distance from the monocrystalline silicon layer increases, has a local maximum, and falls again to the initial value.

10. The semiconductor wafer of claim 1, wherein at least one buffer layer with a different composition is integrated within the graded silicon-germanium layer.

11. The semiconductor wafer of claim 10, wherein the buffer layer with a different composition contains carbon as well as silicon and germanium.

12. The semiconductor wafer of claim 1, wherein the surface of the graded silicon-germanium layer or the surface of an additional silicon-germanium layer with a substantially constant proportion of germanium, have a dislocation density of less than 1·10⁴ cm⁻².

13. The semiconductor wafer of claim 1, wherein the proportion x of germanium at the surface of the graded silicon-germanium layer or of the silicon-germanium layer with a substantially constant proportion of germanium, has a value of 0.1≦x≦0.9.

14. The semiconductor wafer of claim 13, further comprising a strained silicon layer which is adjacent to the graded silicon-germanium layer or to an additional silicon-germanium layer with a substantially constant proportion of germanium.

15. The semiconductor wafer of claim 1, wherein the proportion of germanium at the surface of the graded silicon-germanium layer or of an additional silicon-germanium layer with a substantially constant proportion of germanium, has a value of x=1.

16. A method for production of a semiconductor wafer of claim 1, in which silicon-germanium with a composition Si₁₋ₓGeₓ, where x represents the proportion of germanium and 0<x≦1, is deposited epitaxially on a semiconductor wafer comprising a monocrystalline silicon layer, where x assumes greater values as the thickness of the deposited layer increases, wherein the increase in x slows down as the thickness of the deposited layer increases.

17. A semiconductor wafer comprising a substrate wafer and a relaxed silicon-germanium layer with a composition Si₁₋ₓGeₓ connected, where x represents the proportion of germanium and 0<x≦1, and prepared by the process of claim 1, wherein the surface of the silicon-germanium layer has a dislocation density of less than 1·10⁴ cm⁻².

18. A method for production of a semiconductor wafer of claim 17, in which a semiconductor wafer having a dislocation density at its surface of less than 1·10⁴ cm⁻² is used as a donor wafer, which is connected to a substrate wafer, and in which the thickness of the donor wafer is then reduced such that the monocrystalline silicon layer is completely removed, and the layer adjacent to it and composed of silicon-germanium is partially removed.

19. A semiconductor wafer comprising a substrate wafer and a strained silicon layer is connected thereto, wherein the surface of the strained silicon layer has a dislocation density of less than 1·10⁴ cm⁻².

20. A method for production of a semiconductor wafer of claim 19, in which a semiconductor wafer comprising a strained silicon layer which is adjacent to the graded silicon-germanium layer or to an additional silicon-germanium layer with a substantially constant proportion of germanium is used as a donor wafer, which is connected to a substrate wafer, and in which the thickness of the donor wafer is then reduced such that the monocrystalline silicon layer and the silicon-germanium layer are completely removed.

21. A silicon wafer comprising a substrate wafer and a germanium layer connected thereto, wherein the surface of the germanium layer has a dislocation density of less than 5·10⁵ cm⁻².

22. A method for production of a semiconductor wafer of claim 21, in which a semiconductor wafer wherein the proportion of germanium at the surface of the graded silicon-germanium layer or of an additional silicon-germanium layer with a substantially constant proportion of germanium, has a value of x=1 is used as a donor wafer, which is connected to a substrate wafer, and in which the thickness of the donor wafer is then reduced such that the monocrystalline silicon layer and the layer adjacent to it and composed of silicon-germanium is completely removed, such that only the layer composed of germanium still remains on the substrate wafer.
